(19) United States
(12) Patent Application Publication
(10) Pub. No.: US 2008/0067654 A1
(43) Pub. Date: Mar. 20, 2008

(54) Electronic component package and electronic component device

(75) Inventor: Kenichi Sakaguchi, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 11/898,239

(22) Filed: Sep. 11, 2007

(30) Foreign Application Priority Data
Sep. 15, 2006 (JP) 2006-250319

(51) Int. Cl. H01L 23/02

(52) U.S. Cl. 257/680; 257/E23.18

(57) ABSTRACT

An electronic component package includes, a die pad on which an electronic component is mounted, a radiation plate disposed to be connected to part of the die pad and bent downward, a plurality of leads disposed side by side on a periphery of the die pad, each lead composed of an inner lead disposed on the die pad side and an outer lead connected to the inner lead and bent downward, and a resin portion composed of a lower resin portion formed under the die pad and the inner lead, and a frame-like resin portion formed in a ring shape to stand up on the lower resin portion so that a connection part of the inner lead and an upper surface of the die pad can be exposed, wherein the die pad, the radiation plate and the leads are supported by the resin portion and integrated with each other.

### CROSS-REFERENCE TO RELATED APPLICATIONS

This application is based on and claims priority of Japanese Patent Application No. 2006-250319 filed on Sep. 15, 2006, the entire contents of which are incorporated herein by reference.

### BACKGROUND OF THE INVENTION

1. Field of the Invention

The present invention relates to an electronic component package and an electronic component device, and particularly to an electronic component package suitably applicable to a package for a laser diode, and an electronic component device in which electronic components are mounted on the electronic component package.

2. Description of the Related Art

In the prior art, there has been an optical semiconductor device in which a laser diode is mounted to be hermitically sealed in a package, and which is utilized as a light source. As shown in FIG. 1, in an example of an optical semiconductor device in the prior art, a peltier element 200 is disposed on a metallic base 100, and on the peltier element 200, a laser diode 300 and a control element 320 for controlling the laser diode 300 are mounted. A frame-like metallic part 400 formed in a ring shape to stand upright is brazed on a periphery of the metallic base 100.

In addition, a metallic cap 500 is welded on the frame-like metallic part 400, and the laser diode 300 and the control element 320 are housed in a housing portion S. On a part of the frame-like metallic part 400 corresponding to an outgoing direction of a laser beam emitted from the laser diode 300, a beam outgoing window 400a to which an optical fiber is coupled is disposed.

Furthermore, when the optical semiconductor device in the prior art is viewed from another direction, as shown in FIG. 2, a lead 600 extending from the inside of a package in an outward direction is provided to a side of the frame-like metallic part 400. The lead 600 is sealed and fixed to an opening 400x of the frame-like metallic part 400 with a glass 420. In addition, the laser diode 300 is connected to the lead 600 in an inner portion of the package with a wire 340.

As described above, in the optical semiconductor device in the prior art, heat generated from the laser diode 300 is dissipated to the side of the metallic base 100 through the peltier element 200.

As a technique related to the heat dissipation of such an optical semiconductor device, patent literature 1 (Japanese Patent Application Laid-open Publication No. 2004-146530) discloses a hollow package made of resin on which an imaging device is mounted. In this hollow package, leads are formed on two sides of the hollow package facing each other, and radiation fins made of metal are provided to the remaining sides of the hollow package facing each other.

Also, in patent literature 2 (Japanese Patent Application Laid-open Publication No. 2005-150160), it is disclosed that a radiation plate is caulked and coupled under an element mounting part in a semiconductor device of a premolded type in which, a semiconductor chip such as an optical device is mounted on the element mounting part, a plurality of leads provided around the semiconductor device are sealed with resin, and a hollow is provided on the element mounting part.

In the above-described optical semiconductor device of the prior art, in order to obtain sufficient reliability, it needs to assemble by brazing a costly metallic member (CuW and the like) having most suitable expansion coefficient to the laser diode. In addition, a peltier element is used as radiation means. For this reason, there are problems that manufacturing cost of packages is increased, and that a need for reduction in the manufacturing cost cannot be met easily.

Accordingly, in order to decrease the manufacturing cost of packages, a package with a following structure can be considered (for example, a package similar to the patent literature 1) In the package, a part of an inexpensive lead frame is molded with resin, and cutting and bending processes are performed to form a package, and then a laser diode is mounted on a die pad.

However, in the case of such package, since it is difficult to make a plate of a lead frame extremely thick, and the width of a lead is small, in many cases, sufficient radiation performance cannot be obtained even if the lead is used as a heat dissipation path. Accordingly, it is necessary to separately attach a heat sink and a heat spreader, and there is a limit in reducing the manufacturing cost.

### SUMMARY OF THE INVENTION

It is an object of the present invention to provide an electronic component package and an electronic component device which are capable of obtaining sufficient heat dissipation performance and of being manufactured at low cost.

The present invention relates to an electronic component package which includes, a die pad on which an electronic component is mounted, a radiation plate disposed to be connected to part of the die pad and bent downward, a plurality of leads disposed side by side on a periphery of the die pad, each lead composed of an inner lead disposed on the die pad side and an outer lead connected to the inner lead and bent downward, and a resin portion composed of a lower resin portion formed under the die pad and the inner lead, and a frame-like resin portion formed in a ring shape to stand up on the lower resin portion so that a connection part of the inner lead and an upper surface of the die pad can be exposed, wherein the die pad, the radiation plate and the leads are supported by the resin portion and integrated with each other.

In a preferred mode of the present invention, the die pad has a rectangular shape, and quadrilateral flat plate portions each having a width larger than that of the die pad are provided and connected to both ends of the die pad in a longitudinal direction. The radiation plates are connected to the predetermined sides of the flat plate portions and are bent downward. In addition, a plurality of leads are disposed side by side on the periphery of both ends of the die pad, the ends being parallel to a longitudinal direction of the die pad. Each of the leads includes an inner lead and an outer lead. The outer lead is connected to the inner lead and is bent downward.

Furthermore, the lower resin portion is formed under the die pad, the flat plate portions, and the inner leads. The frame-like resin portion is formed in a ring shape to stand upright on the lower resin portion so that a connection part of the inner leads and an upper surface of the die pad can be exposed. In this way, the die pad, the radiation plates, and the leads are supported by the resin portion and integrated with each other.

The electronic component package of the present invention becomes an electronic component device in such a way that an electronic component is mounted on the die pad and connected to the inner leads using a wire, and that the cap member is firmly fixed on the frame-like resin portion. In a case where a light emitting device (a laser diode) is used as an electronic component, a light transmitting window is provided to a wall of the frame-like resin portion.

In the electronic component package of the present invention, the die pad and the radiation plate are formed of metal (copper alloy, iron-nickel alloy, or the like) having high thermal conductivity. It is preferable that a plurality of radiation plates are bent and provided on desired positions of the flat plate portions on both sides of the die pad. Accordingly, the area of the radiation plate can be set large while reducing the setting area of the entire package. For this reason, heat generated from an electronic component mounted on the die pad is dissipated to outside from the die pad through the radiation plates without particularly providing a heat sink and a heat spreader, thus obtaining sufficient heat dissipation performance.

The electronic component package of the present invention can be manufactured at a cost extremely lower than the case when costly metallic members are brazed and manufactured. This is because part of the inexpensive lead frame having a predetermined pattern is molded using the resin portion, and then the leads and the radiation plates are detached from the lead frame, and are bent and manufactured.

Furthermore, the radiation plates and the leads can be disposed on arbitrary positions of a periphery of the die pad, and at the same time, the number of the radiation plates can be arbitrarily set. For this reason, in a case where it is necessary to control the balance of the heat dissipation of the entire package according to a kind of an electronic component and a mounting position thereof, the widths of the radiation plates and the positions or the number thereof can be optimized according to the characteristics of the electronic component. As a result, unlike the prior art, it is possible to perform temperature control of the entire package without using the peltier element, and cost reduction can be achieved.

As described above, the electronic component package of the present invention can obtain sufficient heat dissipation performance, and concurrently can be manufactured at low cost.

### BRIEF DESCRIPTION OF THE DRAWINGS

FIG. 1 is a sectional view of an example of a optical semiconductor device in the prior art.

FIG. 2 is a sectional view of the optical semiconductor device in the prior art of FIG. 1 viewed from another direction.

FIG. 3 is a perspective view of an electronic component package according to an embodiment of the present invention.

FIG. 4 is a plan view of the electronic component package of FIG. 3 viewed from the above.

FIG. 5 is a sectional view taken along the I-I line of FIG. 4.

FIG. 6 is a plan view showing a state in which a resin portion is molded to a lead frame used for a method of manufacturing the electronic component package according to the embodiment of the present invention.

FIGS. 7A to 7C are sectional views each showing a method of manufacturing the electronic component package according to the embodiment of the present invention. FIG. 7A is a sectional view taken along the II-II line of FIG. 6.

FIG. 8 is a plan view showing a state in which an electronic component is mounted on the electronic component package according to the embodiment of the present invention.

FIG. 9 is a sectional view taken along the III-III line of FIG. 8.

FIG. 10 is a sectional view showing the electronic component device according to the embodiment of present invention.

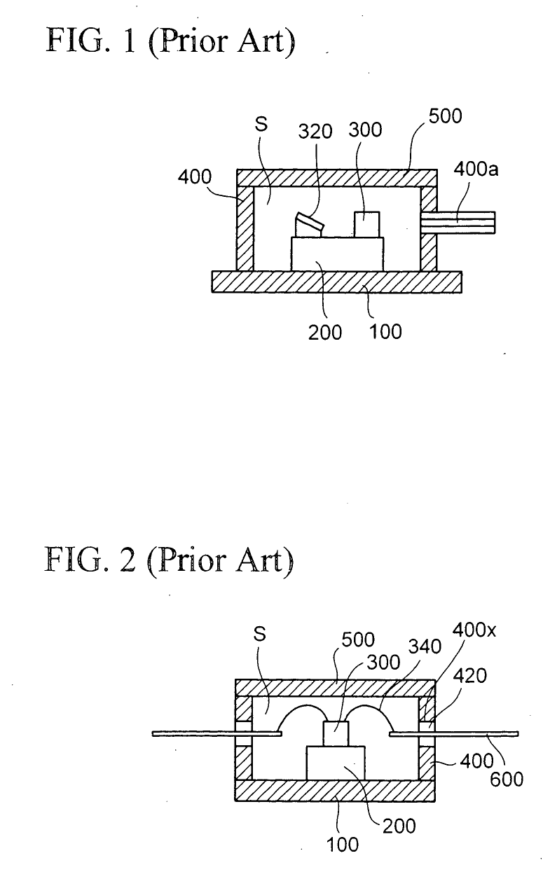

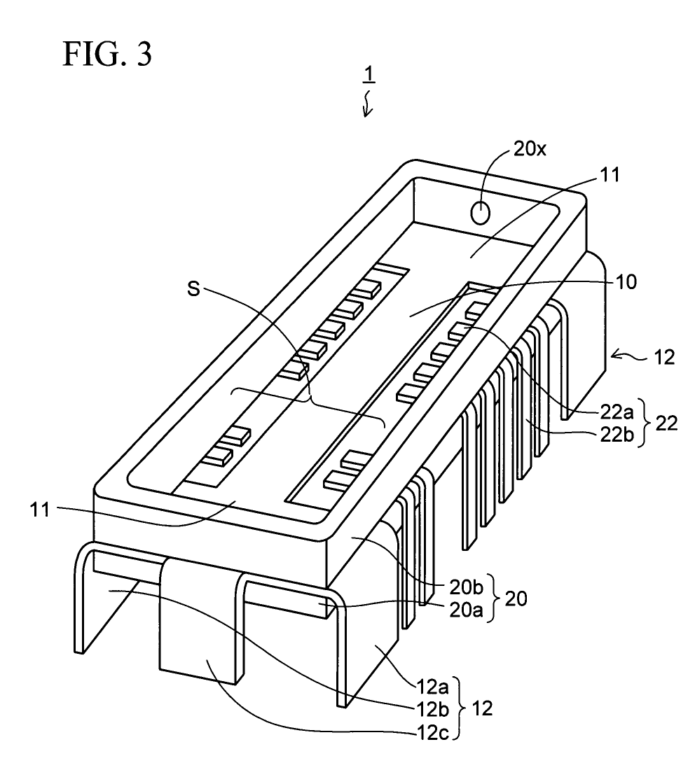

### DETAILED DESCRIPTION OF THE PREFERRED EMBODIMENTS

An embodiment of the present invention is described below with reference to the accompanying drawings.

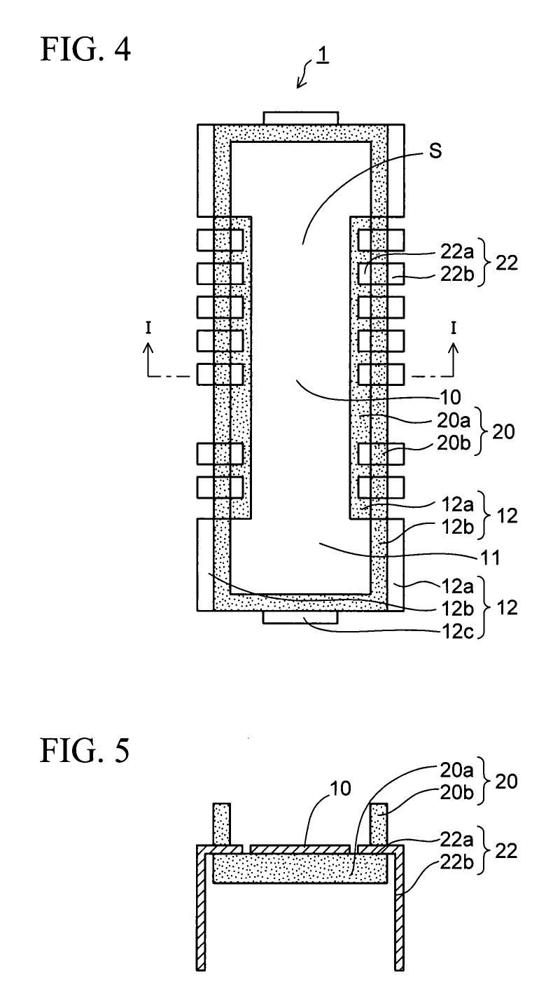

FIG. 3 is a perspective view of an electronic component package of an embodiment of the present invention; FIG. 4 is a plan view of the electronic component package of FIG. 3 viewed from the above; and FIG. 5 is a sectional view taken along the I-I line of FIG. 4.

As shown in FIGS. 3 and 4, in an electronic component package 1 of the present embodiment, flat plate portions 11 are provided and connected to both ends of a rectangular-shaped die pad 10 on which electronic components (a laser diode and the like) are mounted, the flat plate portions 11 being on the same plane as the rectangular-shaped die pad 10. The die pad 10 is constructed to include the flat plate portion 11, and the width of the flat plate portions 11 is set larger than that of the die pad 10.

When the attention is paid to one end (the front side in FIGS. 3 and 4) of the die pad 10, the radiation plates 12 connected to the flat plate portion 11 and bend downward is provided to the flat plate portion 11. The flat plate portion 1i has a quadrilateral shape, and first and second radiation plates 12a, 12b bent downward respectively are provided such that the radiation plates 12a, 12b are connected to the flat plate portion 11 on a pair of sides thereof, the pair of sides which faces each other and is parallel to a longitudinal direction of the die pad 10.

Furthermore, a third radiation plate 12c bent downward is provided such that the third radiation plate 12c is connected to the flat plate portion 11 at the center of a front end of the flat plate portion 11, the front end being opposite to the side of the die pad 10. On the other side of the die pad 10 in a longitudinal direction thereof, the radiation plate 12 having the same constitution is also provided.

Under the die pad 10 and the flat plate portion 11 on the sides of both ends of the die pad 10, a lower resin portion 20a having substantially the same width as the flat plate portion 11 is provided. Referring also to FIG. 5, in the lower side of the die pad 10, the lower resin portion 20a is formed to extend out from both edges of the die pad 10 which are parallel to a longitudinal direction thereof, to the outer periphery of the die pad 10.

Moreover, when the attention is paid to the side (the right side of FIG. 3) of one end which is parallel to a longitudinal direction of the die pad 10, leads 22 are provided to extend downward from an upper end of the lower resin portion 20a at predetermined intervals from the die pad 10. In addition, a plurality of the leads 22 are disposed side by side along a longitudinal direction of the die pad 10 in a state that the leads 22 electrically separated each other. Each of the leads 22 is composed of an inner lead 22a and an outer lead 22b. The inner lead 22a is disposed on the lower resin portion 20a along an outer periphery of the die pad 10, and the outer lead 22b is connected to the inner lead 22a and bent downward at an end of the lower resin portion 20a.

The outer lead 22b is placed on a position where the outer surface of the outer lead 22b corresponds to surfaces of the first and second radiation plates 12a, 12b, and where the length of the outer lead 22b corresponds to lengths of the first and second radiation plates 12a, 12b. In addition, on the other side of the die pad 10 being parallel to a longitudinal direction thereof, the same plurality of leads 22 are disposed side by side along the end of the lower resin portion 20a.

Furthermore, a frame-like resin portion 20b is provided in a ring shape to stand upright, from respective periphery parts of the flat plate portions 11 of both end sides of the die pad 10, to belt-like portions intersecting region except the connection parts of the plurality of inner leads 22a. In other words, the frame-like resin portion 20b is formed on the periphery parts of the lower resin portion 20a such that the connection parts of the inner leads 22a and an upper surface of the die pad 10 are exposed. The resin portion 20 is composed of the lower resin portion 20a and the frame-like resin portion 20b. The resin portion 20 is integrally provided such that the resin portion 20 sandwiches the inner leads 22a and a part of the flat plate portion 11.

Moreover, a light transmitting window 20x is provided to one side of a wall of the frame-like resin portion 20b disposed at one end in a longitudinal direction of the die pad 10. The light transmitting window 20x may be sealed with a glass or may be a hollow through which optical fibers are coupled.

In this manner, the plurality of leads 22 are inserted into the resin portion 20, arranged side by side, and firmly fixed such that the connection parts of each of the inner leads 22a are exposed. In addition, the die pad 10, the radiation plates 12, and the leads 22 are supported by the resin portion 20 and integrated with each other. In addition, a housing portion S in which electronic components are housed is composed of the lower resin portion 20a, the die pad 10, and the frame-like resin portion 20b. The die pad 10, the radiation plates 12, and the leads 22 are made of an inexpensive metal having high thermal conductivity such as copper alloy or iron-nickel alloy (42 alloy).

As described above, in the electronic component package 1 of the present embodiment, the radiation plates 12 bent downward are provided to the predetermined part of the die pad 10, so that a total area of the radiation plates 12 can be set larger than the case of utilizing only narrow leads as a heat dissipation portion.

Accordingly, as will be described later, when electronic components are mounted on the die pad 10 of the electronic component package 1, then an electronic component device is manufactured, heat generated from an electronic component (a laser diode or the like) is dissipated to outside from the die pad 10 through the radiation plates 12 without particularly providing a heat sink and a heat spreader, thus obtaining sufficient heat dissipation performance.

Note that the radiation plates 12 may be directly provided to both ends of the die pad 10 by omitting the flat plate portion 11. Alternatively, in FIG. 3, at least one of the first to third radiation plates 12a to 12c may be provided. Furthermore, the radiation plates 12 which have the similar structure, and which are disposed along with the lead 22 on part of parallel sides to a longitudinal direction of the die pad 10 may be provided. In addition, the die pad 10 is not limited to the rectangular shape, and various kinds of shapes can be adopted. In other words, in the present embodiment, it may be that the radiation plate connected to the die pad and bent downward is provided, and the leads are disposed at the periphery of the die pad, and those elements are integrally supported by the resin portion.

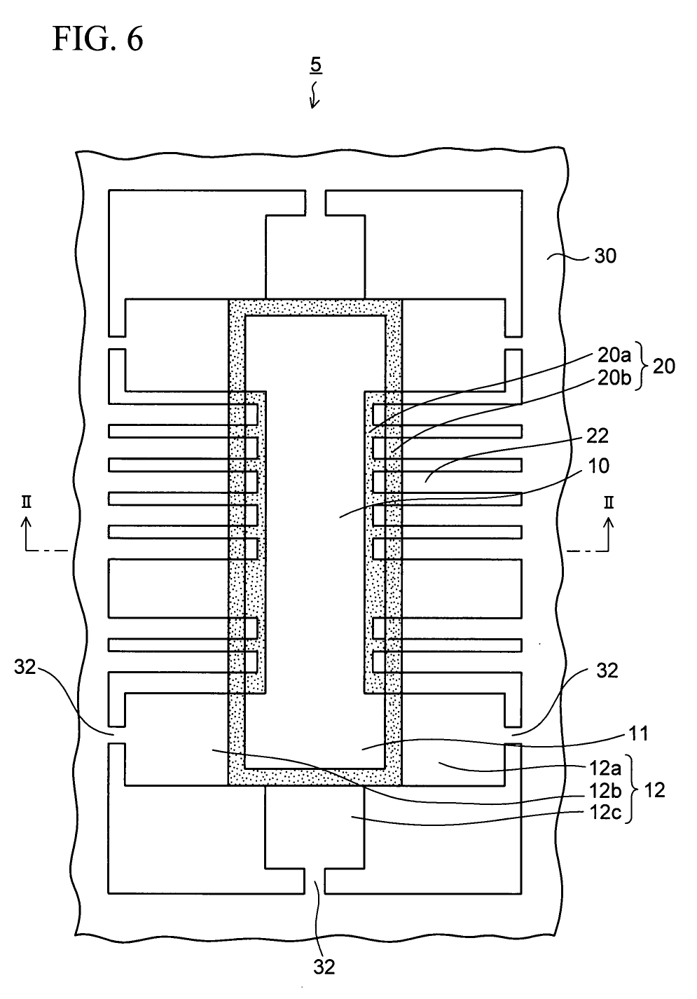

Next, a method of manufacturing the electronic component package 1 of the present embodiment is described. First, a lead frame 5 such as shown in FIG. 6 is prepared. The lead frame 5 can be obtained in such a way that a metal plate made of copper alloy, iron-nickel alloy, or the like is processed by stamping or etching. As shown in FIG. 6, in the lead frame 5, a plurality of leads 22 are connected to and disposed on inner parts of a pair of a frame 30 in the lateral direction thereof.

Furthermore, a rectangular-shaped die pad 10 is disposed inner side of a pair of the plurality of leads 22, and the flat plate portion 11 and the first to third radiation plates 12a to 12c are connected and disposed on the both end sides of the die pad 10. Each of the radiation plates 12a to 12c is supported to be coupled to the coupling portions 32 connecting to the frame 30.

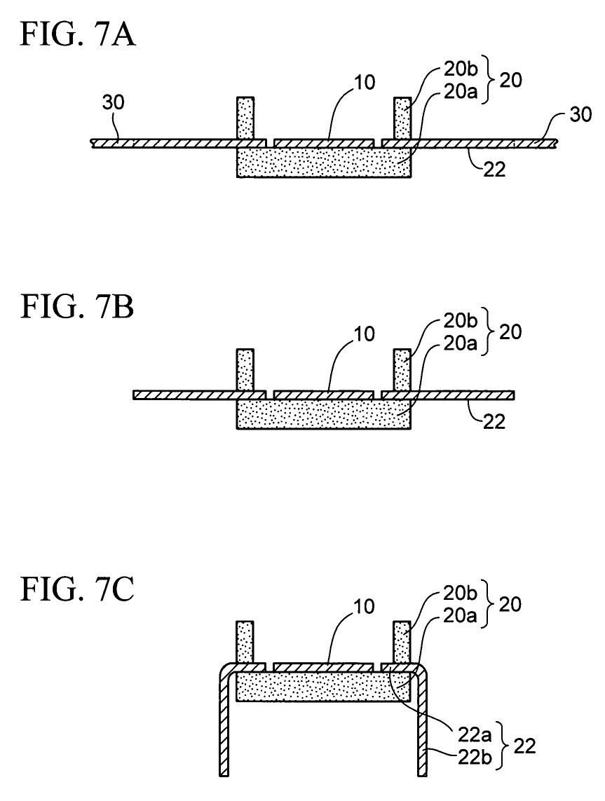

Subsequently, the lead frame 5 is sandwiched by a die (not shown) composed of a lower die and an upper die, and resin is filled into the die and then cured. Thereafter, the dies are detached. Thus, as shown in FIG. 6 and FIGS. 7A to 7C (a sectional view taken along the II-II line of FIG. 6), the lower resin portion 20a is formed under the die pad 10, the flat plate portions 11 and the leads 22, and at the same time, the frame-like resin portion 20b is formed in a ring shape to stand upright on the periphery of the lower resin portion 20a so that the connection parts of the leads 22 can be exposed. Accordingly, the die pad 10, the radiation plates 12, and the leads 22 are supported by the resin portion 20 and integrated with each other.

Next, as shown FIG. 7B, the leads 22 are separated from the frame 30 by cutting root portions of the leads 22 connected to the frame 30. Furthermore, in FIG.6, the first to third radiation plates 12a to 12c are separated from the frame 30 by cutting the coupling portions 32 connected to the first to third radiation plates 12a to 12c. Subsequently, as shown in FIG. 7C, part of the leads 22 extending out from the resin portion 20 is bent downward, thereby, the inner leads 22a and the outer leads 22b connected to the leads 22a and bent downward, which are shown in FIG. 3, are obtained.

Furthermore, the first to third radiation plates 12a to 12c each extending out from the resin portion 20 are bent downward, thereby the first to third radiation plates 12a to 12c bent downward from the flat plate portion 11, as shown in FIG. 3, are obtained. In this manner, the electronic component package 1 of the present embodiment is obtained.

As described above, the electronic component package 1 of the present embodiment can be manufactured at a cost extremely lower than the case when costly metallic members are brazed and manufactured. This is because part of the inexpensive lead frame 5 (copper alloy, iron-nickel alloy, or the like) is molded using the resin portion 20, and then the leads 22 and the radiation plates 12 are detached from the frame 30, and thereafter bent and manufactured.

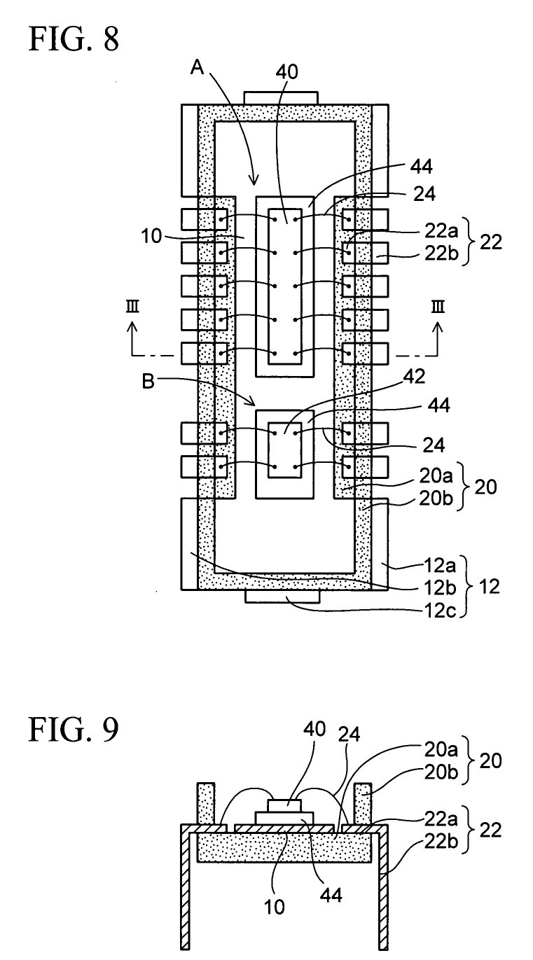

Next, a method of mounting electronic components on the electronic component package 1 of the present embodiment is described. As shown in FIGS. 8 and 9, first, a laser diode 40 (a light emitting device) is mounted, as the electric component, on a first mounting area A of the die pad 10 of the electronic component package 1 with a sub-mount 44. The laser diode 40 is mounted so that a laser beam can be emitted to the outside through the light transmitting window 20x (refer to FIG. 3) which is provided to the wall of the frame-like resin portion 20b.

Subsequently, connection terminals of the laser diode 40 and connection parts of inner leads 22a are connected with wires 24. Furthermore, in the same manner, a control semiconductor chip 42 for monitoring and controlling a laser beam emitted by the laser diode 40 is mounted on a second mounting area B of the die pad 10 with a sub-mount 44. Furthermore, in the same manner, connection terminals of the control semiconductor chip 42 and connection parts of the inner leads 22a are connected with wires 24.

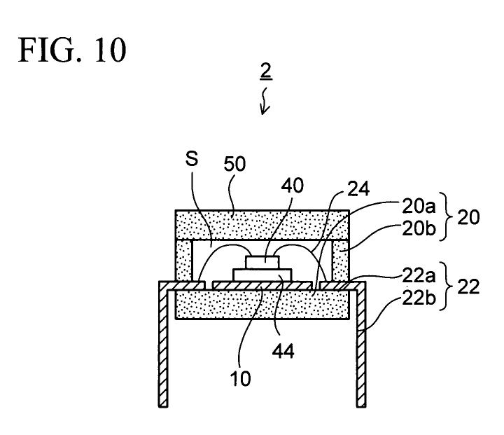

Next, as shown in FIG. 10, a cap member 50 made of ceramic, metal, or the like is firmly fixed on the frame-like resin portion 20b. Accordingly, the laser diode 40 and the control semiconductor chip 42 are housed to be hermetically sealed in a housing portion S which is composed of the lower resin portion 20a, the die pad 10, the frame-like resin portion 20b, and the cap member 50. In this way, an electronic component device 2 of the present embodiment is obtained. In the electronic component device 2 of the present embodiment, the outer leads 22b are inserted into sockets of a wiring substrate or other method and connected thereto, and the radiation plates 12 are connected to heat dissipation path of the wiring substrate.

In the electronic component device 2 of the present embodiment, as described above, since the radiation plates 12 connecting to the die pad 10 are provided so as to be bent downward, the area of the radiation plates 12 can be set large.

Accordingly, it is capable of obtaining high heat dissipation performance.

In the present embodiment, although the radiation plates 12 are symmetrically provided to both of the ends of the die pad 10, the radiation plates 12 and the leads 22 can be disposed on arbitrary positions of the periphery part of the die pad 10. Furthermore, the number of the radiation plates 12 may be arbitrarily set.

Accordingly, in the case where it is necessary to control the balance of the heat dissipation of the entire package according to a kind of the laser diode 40 and mounting position thereof, it can control by optimize the width, the position and the number of the radiation plates 12 such that the most suitable heat dissipation characteristic of the laser diode 40 is obtained.

For example, in a case where the laser diode 40 is mounted on an end side of the die pad 10, by increasing the total area of the radiation plates 12 closer to the laser diode 40, heat dissipation can be performed in the package with good balance. Alternatively, the radiation plates 12 can be bent and provided to part of the die pad 10 between the laser diode 40 and the control semiconductor chip 42 so as to control heat dissipation.

Accordingly, unlike the prior art, it is not necessary to control temperature by providing a peltier element under a laser diode, so that cost reduction can be achieved.

What is claimed is:

1. An electronic component package comprising:
a die pad on which an electronic component is mounted;
a radiation plate disposed to be connected to part of the die pad and bent downward;
a plurality of leads disposed side by side on a periphery of the die pad, the each lead composed of an inner lead disposed on the die pad side and an outer lead connected to the inner lead and bent downward; and
a resin portion composed of a lower resin portion formed under the die pad and the inner lead, and a frame-like resin portion formed in a ring shape to stand up on the lower resin portion so that a connection part of the inner lead and an upper surface of the die pad can be exposed,
wherein the die pad, the radiation plate and the leads are supported by the resin portion and integrated with each other.

2. The electronic component package according to claim 1, wherein the die pad has a rectangular shape;
frat plate portions each having a width larger than that of the die pad, and provided and connected to both ends of the die pad in a longitudinal direction;
the radiation plate is connected to the flat plate portions and bent downward; and
the plurality of leads are disposed on peripheries of both ends of the die pad, the ends being parallel to a longitudinal direction of the die pad.

3. The electronic component package according to claim 2, wherein the frat plate portion has a quadrilateral shape; and
the radiation plate is connected to at least one side of the flat plate portions and bent downward.

4. The electronic component package according to claim 1, wherein a light transmitting window is provided in the frame-like resin portion disposed at one end side in the longitudinal direction of the die pad.

5. The electronic component package according to claim 1, wherein the position and width of the radiation plate are adjusted, so as to be controlled the balance of heat dissipation performance in the package according to characteristics of the electronic component mounted on the die pad.

6. The electronic component package according to claim 1, wherein the die pad, the radiation plates and the leads are made of any one of copper alloy and iron-nickel alloy.

7. An electronic component device comprising:
the electronic component package according to any one of claims 1 to 6;
an electronic component mounted on the die pad and connected to a connection part of the inner lead by a wire; and
a cap member fixed on the frame-like resin portion and housing the electronic component.

8. The electronic component device according to claim 7,
wherein the electronic component package is the one recited in claim 4; and
the electronic component is a light emitting device.

9. The electronic component device according to claim 8, wherein a control semiconductor chip for controlling the light emitting device is further mounted on the die pad, and the control semiconductor chip is connected to a connection part of the inner lead by a wire.
